(19) United States
(12) Patent Application Publication
(10) Pub. No.: US 2012/0227796 A1
(43) Pub. Date: Sep. 13, 2012

(54) OPTICS WITHIN A CONCENTRATED PHOTOVOLTAIC RECEIVER CONTAINING A CPV CELL

(75) Inventors: DAVID DOUGHERTY, Pleasanton, CA (US); Arlie Conner, Portland, OR (US)

(73) Assignee: GREENVOLTS, INC., Fremont, CA (US)

(21) Appl. No.: 13/044,418

(22) Filed: Mar. 9, 2011

(51) Int. Cl. H01L 31/06

(52) U.S. Cl. 136/255

(57) ABSTRACT

A multiple junction photovoltaic cell is optically coupled to the Fresnel lens with teeth. The set of teeth within a given ring of a ringed pattern of teeth on the Fresnel lens may have 1) varying surface angles of different teeth across the lens, 2) varying refractive indexes of the different teeth or 3) a combination of both. The differing surface angles or refractive indexes of different teeth within a given ring of a ringed pattern of teeth establish multiple focal lengths aimed at five or more different axial target focal points within an anticipated zone of operation relative to the multiple junction photovoltaic cell to create a window of averaged intensity of light defined by the five or more different axial target focal points.

### RELATED APPLICATIONS

This application is a continuation in part of the following and claims the benefit of and priority to U.S. Provisional Application titled “SINGLE ELEMENT LENS COUPLED TOTAL-INTERNAL REFLECTION PRISM SECONDARY” filed on Mar. 11, 2010 having application Ser. No. 61/313,022, and U.S. Provisional Application titled “SELF-ALIGNING CPV INTEGRATED OPTICAL ARRAY” filed on Mar. 11, 2010 having application Ser. No. 61/313,021.

### FIELD OF THE INVENTION

Embodiments of the invention generally relate to optics within a Concentrated PhotoVoltaic receiver containing a CPV cell.

### BACKGROUND OF THE INVENTION

A Fresnel lens may have teeth in some kind of ring pattern where all the teeth in a given ring have the same surface angle and are made out same material. Teeth of different rings may have differing surface angles across its aperture but a common effective focal length aimed where an idealized collimated beam converges to a single focus point.

### SUMMARY OF THE INVENTION

Various methods and apparatus are discussed for a Photovoltaic (PV) system. A PV power unit may include a Fresnel lens with a plurality of teeth, which provide a distributed set of two or more axial focal lengths to mitigate chromatic aberration as well as changes in focal length due to changes in temperature of the material forming the lens with teeth.

A multiple junction photovoltaic cell is optically coupled to the Fresnel lens with teeth. A set of teeth within a given ring of a ringed pattern of teeth on the Fresnel lens have 1) varying surface angles of different teeth across the lens, 2) varying refractive indexes of the different teeth or 3) a combination of both, to establish multiple focal lengths aimed at three or more different axial target focal points within an anticipated zone of operation relative to the multiple junction photovoltaic cell to create a window of averaged intensity of light defined by the three or more different axial target focal points.

### BRIEF DESCRIPTION OF THE DRAWINGS

The drawings refer to embodiments of the invention in which:

FIG. 1 illustrates a diagram of an embodiment of a CPV power unit that includes a Fresnel lens with a plurality of teeth providing a distributed set of two or more axial focal lengths to mitigate chromatic aberration as well as changes in focal length due with changes in temperature of the material forming the lens with teeth.

FIG. 2 illustrates a diagram of an embodiment of the incident light rays of a distributed focus lens having five focal lengths interleaved across the set of teeth on the lens aimed at different axial target locations within the window.

FIG. 3a illustrates a diagram of an embodiment of the surface angles of the teeth in each given concentric ring are uniform within that ring but each ring aims at a different target focal point to establish the multiple foci (focal lengths) aimed at five or more different axial target focal point locations within the window of averaged intensity of light that corresponds in size to an anticipated window of operation for the CPV power unit.

FIG. 3b shows an exploded view of an embodiment of FIG. 3a with two of the target focal points for each color.

FIGS. 4a-4d illustrate a diagram of an embodiment of an effect of homogenization of focal spot size of different wavelength colors on a surface of a multiple junction solar cell.

FIGS. 5a and 5b illustrate diagrams of an embodiment of the surface angles of different teeth are interleaved in each of the two or more concentric rings within that ring in the ringed pattern across the lens and are set to create at least multiple focal points for two or more colors in the visible light spectrum to define the boundaries of the window of averaged intensity of light to reduce effects of lens temperature change on the light intensity distribution of different wavelengths in the window of averaged intensity of light defined by these multiple focal points.

FIG. 6 illustrates a diagram of an embodiment of a set of teeth within a given ring of a ringed pattern of teeth on the Fresnel lens having varying surface angles of different teeth across the lens.

FIG. 7 shows a diagram of an embodiment of the focal region of this lens using thin-lens central rays to approximate image sizes.

FIG. 8 illustrates a diagram of an embodiment of a window of averaged intensity of light defined by the set of multiple different focal points along the axial length for the two or more colors.

FIG. 9 illustrates example focal spot sizes for the different colors in the incident light of a lens designs with a single focal point.

FIG. 10 illustrates a diagram of an embodiment of a total internal reflection (TIR) prism having a domed shaped top portion and trapezoidal bottom portion that is used as a secondary concentrating mirror surface for the multiple junction photovoltaic cell.

FIG. 11 illustrates a diagram of an embodiment of a Fresnel lens directing light to a secondary optic to concentrate solar radiation to a photovoltaic cell in a receiver assembly.

FIG. 12 Illustrates a diagram of an embodiment of an example calculated secondary walkoff transmission through an aperture versus incidence angle.

FIG. 13 illustrates a diagram of an embodiment of a Fresnel lens focusing light to the secondary shaped to concentrate that light onto the underlying PV cell.

FIG. 14 illustrates a diagram of an embodiment of the secondary optic working by fitting a trapezoidal TIR prism with a curved front surface (dome) that refracts the incident light beams from the primary Fresnel lens into alignment with the trapezoidal portion of the prism's acceptance angle as the incident light beams from the primary Fresnel lens walk across a face of the curved front surface of the secondary optic.

FIG. 15 illustrates a diagram of an embodiment of the shape of the refractive secondary dome and illustrates the concentrating action of such a device.

FIG. 16 illustrates a diagram of an embodiment of example TIR action in a trapezoidal portion of the prism.

FIG. 17 illustrates an example of TIR action in a rectangular prism homogenizer rather than a trapezoidal prism.

FIGS. 18a-c illustrate a diagram of an embodiment of a single-element domed prism shape that increases transmission of light through to a flat-top prism.

FIG. 19 shows an example graph of ray tracing results for a standard flat-top trapezoidal TIR prism of acceptance vs. incidence angle of light from the primary lens.

FIG. 20 illustrates a diagram of an embodiment of an aspheric lens profile construction.

FIG. 21 illustrates a diagram of an embodiment of range of dimensions of the curvature of the domed surface, which is set to match the angular distribution of the light from the primary focus element to the acceptance angles of the TIR trapezoidal portion of the prism.

While the invention is subject to various modifications and alternative forms, specific embodiments thereof have been shown by way of example in the drawings and will herein be described in detail. The invention should be understood to not be limited to the particular forms disclosed, but on the contrary, the intention is to cover all modifications, equivalents, and alternatives falling within the spirit and scope of the invention.

### DETAILED DISCUSSION

In the following description, numerous specific details are set forth, such as examples of specific optical signals, named components, number of mirrors, etc., in order to provide a thorough understanding of the present invention. It will be apparent, however, to one of ordinary skill in the art that the present invention may be practiced without these specific details. In other instances, well known components or methods have not been described in detail but rather in a block diagram in order to avoid unnecessarily obscuring the present invention. Further specific numeric references such as first tooth, may be made. However, the specific numeric reference should not be interpreted as a literal sequential order but rather interpreted that the first tooth is different than a second tooth. Thus, the specific details set forth are merely exemplary. The specific details may be varied from and still be contemplated to be within the spirit and scope of the present invention.

In general, a method, apparatus, and system are described in which an efficient highly concentrating photovoltaic (CPV) cell with a linearly focused Fresnel lens and secondary optic may be organized into a CPV power unit. The features of the concepts discussed herein may also be used in general photovoltaic systems that do not have a concentrating secondary optic as well. The CPV power unit has a Fresnel lens with a plurality of teeth. The plurality of teeth provide a distributed set of two or more axial focal lengths to mitigate chromatic aberration as well as changes in focal length due to changes in temperature of the material and corresponding refractive index of the material forming the lens with teeth. A multiple junction photovoltaic cell is optically coupled to the Fresnel lens with teeth. The set of teeth within a given ring of a ringed pattern of teeth on the Fresnel lens may have 1) varying surface angles of different teeth across the lens, 2) varying refractive indexes of the different teeth or 3) a combination of both. The differing surface angles or refractive indexes of different teeth within a given ring of a ringed pattern of teeth establish multiple focal lengths aimed at five or more different axial target focal points within an anticipated zone of operation relative to the multiple junction photovoltaic cell creates a window of averaged intensity of light defined by the five or more different axial target focal points.

Additionally, a total internal reflection prism (TIR) may have a domed shaped top portion and trapezoidal bottom portion and be used as a secondary concentrating mirror surface. The TIR prism can be optically coupled between the multiple junction photovoltaic cell and the Fresnel lens with teeth.

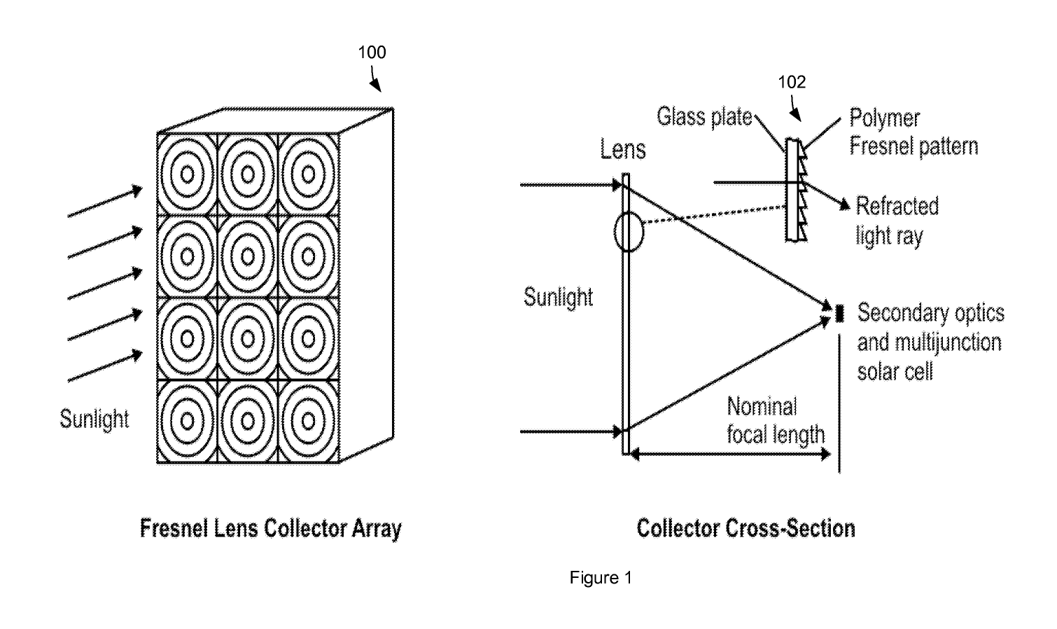

FIG. 1 illustrates a diagram of an embodiment of a CPV power unit that includes a Fresnel lens 100 with a plurality of teeth 102 providing a distributed set of two or more axial focal lengths to mitigate chromatic aberration as well as changes in focal length due with changes in temperature of the material forming the lens with teeth. Each Fresnel lens features a Fresnel prism relief pattern of teeth made of silicone or a similar polymer on the bottom of a flat glass panel. Such lenses are potentially low cost because the polymer can be printed, molded, or otherwise patterned on the glass panel. These polymer materials are stable under prolonged light exposure and the outward facing glass surface can be readily cleaned. An array of CPV power units, each use a flat, square polymer Fresnel lenses with teeth in a concentric ring pattern.

In each CPV power unit a multiple junction photovoltaic cell optically couples to the Fresnel lens with teeth. An example four concentric rings are in the ringed pattern of the Fresnel lens. A set of teeth within a given spiral/concentric ring of the ringed pattern of teeth on the Fresnel lens have 1) varying surface angles of different teeth (prisms) across the lens, 2) varying refractive indexes of the different teeth or 3) a combination of both, to establish multiple focal lengths aimed at three or more different axial target focal points within an anticipated zone of operation relative to the multiple junction photovoltaic cell in order to create the window of averaged intensity of light defined by the three or more different axial target focal points. Note, the ringed pattern of teeth may be in any number of shapes such as rasterized, spiral, concentric and other similar shapes.

Each Fresnel lens focuses light directly onto the multiple junction solar cell or via suitable secondary optic. Light enters from the top/front surface of the lens, passing through the front surface and then teeth of the lens. The Fresnel lens redirects the light rays via the set of teeth to focus the spot of the light beam on the PV cell. In another example embodiment, the Fresnel primary mirror redirects the light rays via the set of teeth to a domed shaped secondary mirror, which then reflects the concentrated beam to the walls of the trapezoidal shaped portion of the prism and onto the PV cell.

The Fresnel mirror may be formed on a glass substrate, and the ring pattern can be fabricated using standard plastic (acrylate or silicone) molding techniques. Here, the Fresnel is formed prism teeth facets on one side and a flat plano surface on the other side. This allows the use of a solid glass top layer with the teeth pattern molded into it.

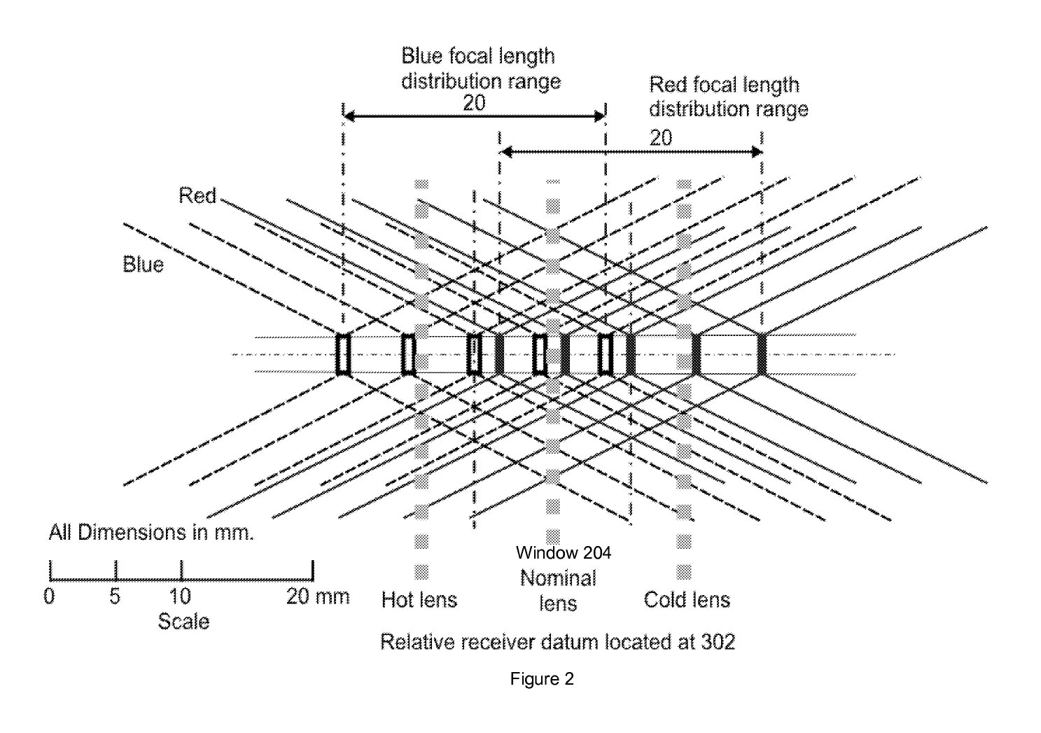

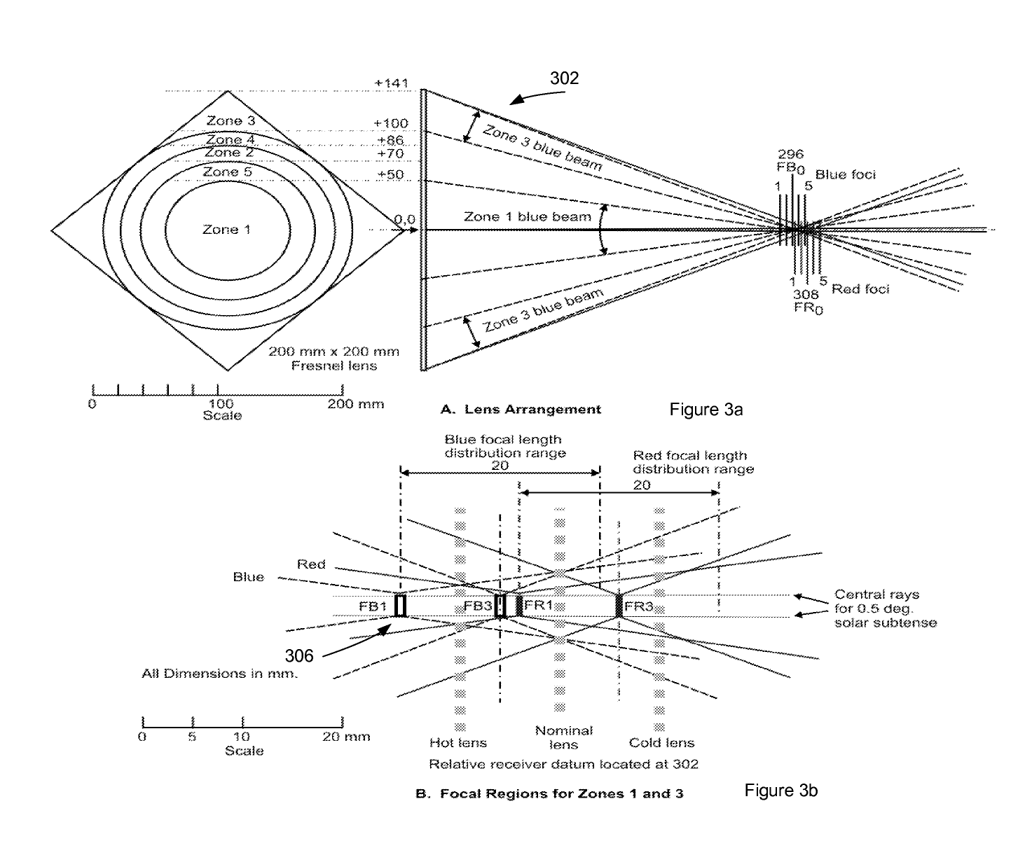

FIGS. 2, 3a and 3b show a lens arrangement with the teeth configured to create an example five-focal length to five target focal point locations for two colors, Blue and Red, in the incident light ray. For a given normal multiple colored incident wavelength of light the focal length of Blue colored light is located at a different location than the focal length of Red colored light from the same multiple colored incident light ray passing through the same tooth. The Fresnel design proposed here uses multiple focal lengths (>>2) aimed at multiple focal points for two or more colors in the incident light in a single lens.

FIG. 2 illustrates a diagram of an embodiment of the incident light rays of a distributed focus lens having five focal lengths interleaved across the set of teeth on the lens aimed at different axial target locations within the window 204. In the figure, Blue color wavelengths are the dashed lines, solid colored lines are the Red color wavelengths, open rectangles are the Blue target focus points, and solid rectangles are the Red target focus points. The focal lengths are spaced five mm apart such that the sets span 20 mm window of operation for each color and an overlap of greater than 50% between the windows of the colors. Each set exhibits 12 mm of chromatic aberration and 20 mm of temperature shift. The figure shows the position of a “receiver datum” of the secondary optics relative to the foci for hot, nominal, and cold lens temperatures. It is apparent that the secondary optics requires a large aperture to collect the extreme diverging rays from the shortest Blue focus when the lens is cold, or to collect the converging rays for the longest Red focus when the lens is hot.

FIG. 3a illustrates a diagram of an embodiment of the surface angles of the teeth 302 in each given concentric ring are uniform within that ring but each ring aims at a different target focal point to establish the multiple foci (focal lengths) aimed at five or more different axial target focal point locations within the window of averaged intensity of light that corresponds in size to an anticipated window of operation for the CPV power unit. In the figure, Blue color wavelengths are the dashed lines, solid colored lines are the Red color wavelengths, open rectangles are the Blue target focus points, and solid rectangles are the Red target focus points. FIG. 3b shows an exploded view of an embodiment of FIG. 3a with two of the target focal points for each color, such as a first target focal point 306. The different target focal points for the focal lengths are spaced set distances, such as five mm, apart such that the set of different target points spans a distance, such as 20 mm, window of operation centric around the multiple layer solar cell under nominal conditions. In this example, the 20 mm size of the window for each color with significant overlap between the colors was set to correspond to the incident light exhibiting 12 mm of chromatic aberration and 20 mm of temperature shift over the anticipated window of operation of the CPV power unit.

The Fresnel design proposed here uses multiple focal lengths (>>2) aimed at multiple focal points for two or more colors in the incident light in a single lens. A range along the optical axis, where the light is to be concentrated, is first selected. The position of the middle of the range will be the nominal focal distance of the lens, given by the desired F-number and aperture of the lens. A set of target focal points is then defined along this range, dividing the range into a number of bins. The number and spacing of the target focus points are design parameters. The target focal points may be evenly spaced or distributed non-uniformly. The lens design then proceeds by calculating for each lens tooth the surface angle necessary to direct light from that tooth to one of the target focal points for that color.

Overall, the Fresnel lens with the set of teeth will have a nominal focal length configured for that Fresnel lens; however, by changing the angle of the surface layer for the set of teeth (or refractive index) small fine tuning of the exact focal point can be achieved (with the creation of a distributed set of focal points for two more colors within an incident light beam).

The mapping of the surface angle (or refractive index of the material) of the teeth of the lens to the target focal points can be done in a number of ways. One way is the mapping of the surface angle (or refractive index of the material) of the teeth of the lens and alternating that surface angle or refractive index for the teeth within each ring to achieve multiple target focal points. Another way is the mapping of the surface angle (or refractive index of the material) of the teeth of the lens to the target focal points and then divide the Fresnel lens into a number of concentric rings, with each ring focusing to one of the target focal length points. The number of teeth in each ring can be adjusted to provide equal power to each target point. The target focus points are selected so that the spot sizes of the different colors in the incident light will significantly overlap in the window/region established by those multiple target point locations. The size of the window is approximately matched to the anticipated shift in focal length over the anticipated window of operation due to temperature changes, chromatic aberration, or both.

As discussed, the surface angle (or refractive index of the material) of the teeth of the lens can be mapped to the target focal points by interleaving the surface angle of neighboring teeth within a given group or ring of teeth. Here, each tooth is directed to a target focal point given by its tooth number modulo the number of target points. In this way, as one moves radially across the lens, the teeth sweep along the set of target focal points repeatedly. This rasterizing of focal lengths in a given window of operation provides averaging over the surface of the lens. Dirt or defects on the lens will not preferentially affect power directed to one of the target spots. The rasterizing also ensures that approximately equal power is delivered to each target point. The mapping of the surface angle (or refractive index of the material) of the teeth of the lens to the multiple different target focal points by interleaving the teeth with alternating surface angles of the teeth within a given ring of a pattern creates the multiple different target focus points in order to create the averaging window of light intensity centric around the focal length of the multiple junction PV cell.

To provide additional averaging, the sub-ranges can in turn be divided into a set of target focus points. Within each lens tooth group, teeth can be mapped to the points target points in the sub range. In the limit, each lens tooth could be directed to its own target point.

Although the exact focal length to the surface of the PV cells actually shifts around during operation of the optical power unit due to the effects of temperature shift, the surface of the PV cell is exposed to roughly the same average intensity of light due to the overlap of different color's spot sizes in the window of target focal lengths created by interleaving the setting of the surface angle of the teeth of the Fresnel lens. This rasterizing of focal lengths in a given window of operation provides averaging over the surface of the lens. Distributing the concentrated energy along the optical axis provides improved averaging to combat the temperature and chromatic effects, which primarily cause simple shifts of focus along the optical axis.

The set of different axial focal points lengths generated by the differing surface angles of the teeth are chosen to be spaced a set distance apart to create the window of averaged intensity of light with overlapping spot sizes/intensity distribution on the surface of the PV cell for different colors in the light wave spectrum which approximately matches 1) an amount of shift in focal length due to anticipated chromatic aberration during operation, 2) the amount of shift in focal length due to change in refractive index of the material making up the teeth due to temperature changes over the normal range of operation of the CPV power unit, or 3) both.

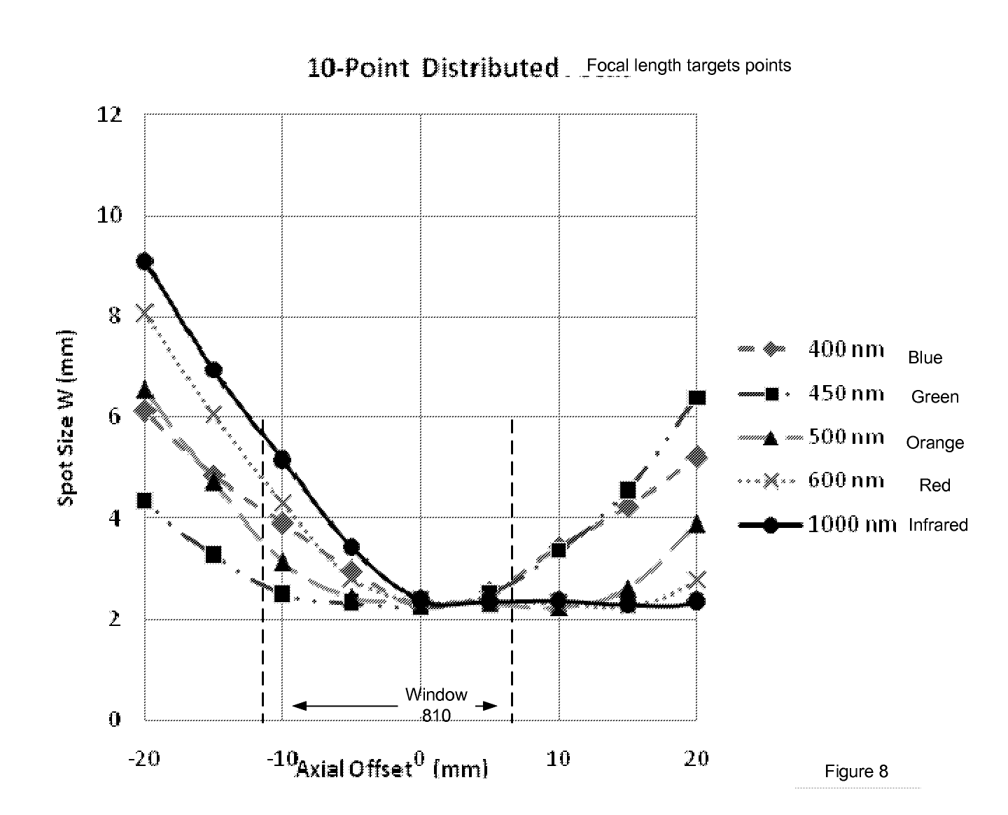

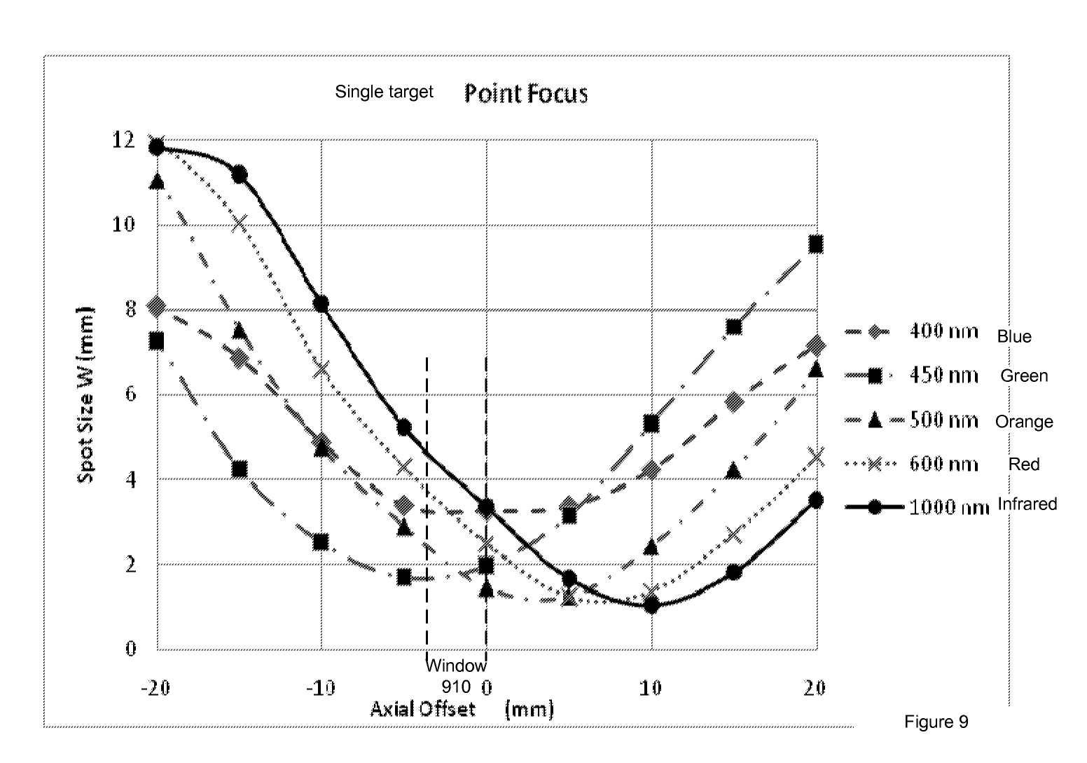

FIG. 8 illustrates a diagram of an embodiment of a window of averaged intensity of light 810 defined by the set of multiple different focal points along the axial length for the two or more colors. The focal spot size of the Red colored light is shown with the dotted line with Xs. The focal spot size of the Red colored light is shown with the dashed line with diamonds. The zone where the diameter of the spot size created by the different target focus points for the Red colored wavelengths matches approximately in size with the diameter of the spot size created by the different focal length target points for the Blue colored wavelengths at given axial distance from the Fresnel lens is much larger for the averaged intensity of light implementation over a Fresnel lens with a single target focus point. Please see the diagram for a 10 target focal point Fresnel lens where at the left hand side of the window the Spot size in Red is about 4.8 mm and the spot size of the Blue light is about 4.3 mm. On the right hand side of the window, the spot size in Red is about 2.2 mm and the spot size of the Blue light is about 2.5 mm. For the majority of the 9 mm wide window of averaged intensity, the spot sizes of Blue and Red are about the same size. In contrast see FIG. 9 the single focal length Fresnel, where a window 910 of the spot sizes of where the colors is approximately matched in spot size ratios and maybe has a width of about 2-3 mm. This single focal length window 910 is both smaller than the PV cell size of 5 mm and when the window 910 shifts for temperature changes during operation, then large swings in light intensity is experienced on the PV cell and even within different sub regions within the PV cell.

The extreme/edge focal lengths (1 and 5) can be assigned to central lens zones, while the middle focal length is assigned to the lens corners. This arrangement reduces the extreme ray angles for the extreme focal points, as shown by the zone 1 rays in the detail figure.

In another embodiment, the Fresnel lens with multiple target focus points optically couples to a secondary optic for concentrating solar radiation onto a photovoltaic chip. It is comprised of a primary Fresnel lens with the set of teeth and a secondary mirror surface, which act together to provide the multiple focal spots.

For best efficiency, the solar cell is a multi-layer/multi-junction device designed to convert as much of the solar spectrum reaching the Earth's surface as feasible. For discussion purposes, the convertible Light wave spectrum extends from a short-wavelength (say 500 nm) light, herein called “Blue”, to a long-wavelength (say 980) near-infrared light, herein called “Red”.

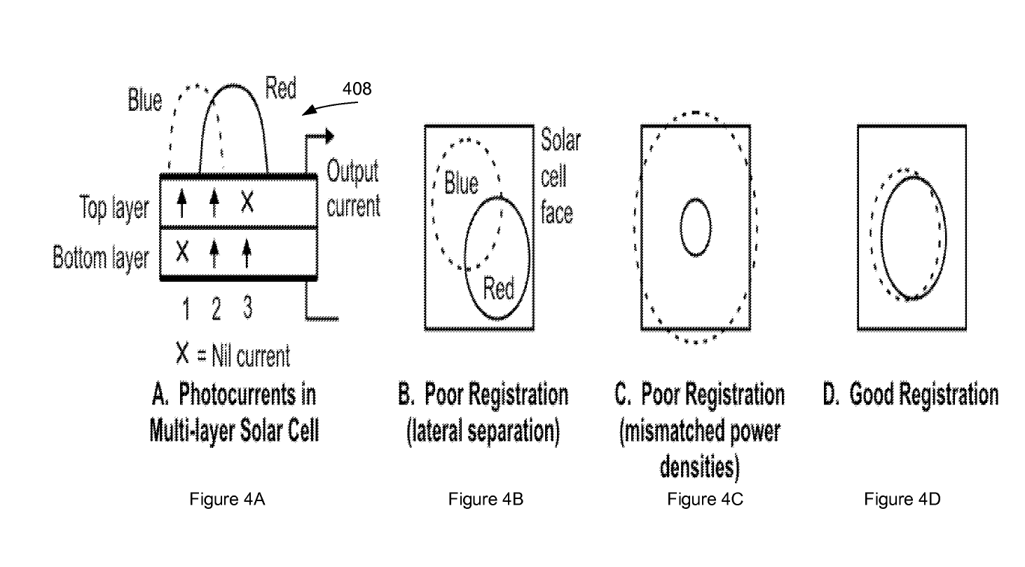

FIGS. 4a-4d illustrate a diagram of an embodiment of an effect of homogenization of focal spot size of different wavelength colors on a surface of a multiple junction solar cell. The focal properties of a flat polymer Fresnel lens may be tailored to best accommodate the spectral response characteristics of multi-layer solar cells. FIG. 4A-4D illustrate these characteristics for a two-layer solar cell, which readily extend to cells have three or more layers responsive to three or more spectral bands.

FIG. 4A shows the color registration of a distribution of Blue and Red light on a multi-layer photocell. The top and bottom layers of the solar cell 408 generate photocurrents responsive to Blue and Red light, respectively. In the figure, Blue color wavelengths are the dashed lines, solid colored lines are the Red color wavelengths. In region 2, which is illuminated by both wavelengths, the photocurrents readily contribute to the cell's output current. In region 1, photocurrent is generated only in the top layer. There are relatively fewer carriers generated in the same region of the bottom layer, and the flow of the top layer current to conductive region 2 of the bottom layer is impeded by large lateral resistance. Therefore, the top layer photocurrent in region 1 is largely dissipated (recombined) within the layer. The same recombination occurs with the bottom layer current in region 3. In essence, the layers within the cell are essentially electrically connected in series and thus the photocurrent out is limited by the layer producing the lowest amount of current.

FIG. 4B reproduces the poor lateral color distribution just discussed. FIG. 4C shows poor color registration due to different power densities and much wider focal spot sizes among the color wavelengths. This reduces cell efficiency because the bottom layer photocurrent is concentrated in region where the top layer is relatively non-conductive. FIG. 4D shows good color registration with homogenization of focal spot size of different wavelength colors leading to good cell efficiency: The colors are relatively well registered and of similar power densities.

This design achieves 1) a more uniform photocurrent generated from the different layers within the multi-junction photovoltaic solar cell and 2) a minimization of areas of high light intensity on the surface of the solar cell because the light intensity is more spread out and homogenized across the entire surface area of the cell. Some areas where the single small spot size focused on the surface could have several times the sun concentration on that area of the surface of the PV cell than other areas on the PV cell.

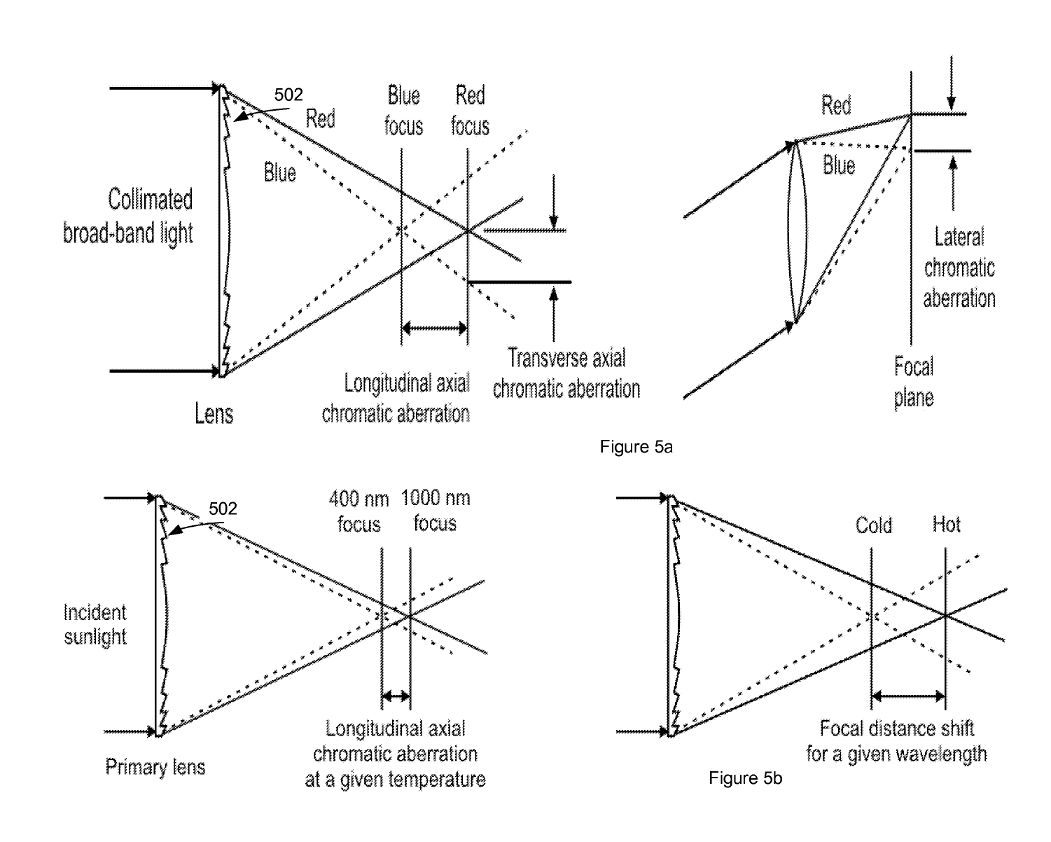

FIGS. 5a and 5b illustrate diagrams of an embodiment of the surface angles of different teeth 502 are interleaved in each of the two or more concentric rings within that ring in the ringed pattern across the lens and are set to create at least multiple focal points for two or more colors in the visible light spectrum to define the boundaries of the window of averaged intensity of light to reduce effects of lens temperature change on the light intensity distribution of different wavelengths in the window of averaged intensity of light defined by these multiple focal points.

FIGS. 5a and 5b also show the primary lens focal distance and the effect of wavelength differences and temperature difference on the focal distance. Although silicone and polymer materials used in the Fresnel lens with teeth have desirable cost and manufacturing benefits, they exhibit an index of refraction characterized by both large wavelength dependence (dispersion) over the solar radiation spectrum of interest as well as large temperature dependence. Dispersion causes axial chromatic aberration, in which light of different wavelengths is focused at difference distances from the lens (FIG. 5a). This aberration can be quantified as longitudinal axial chromatic aberration (difference in focal length over wavelength range of interest) and transverse chromatic aberration (e.g., the radius of the Blue beam spot in the Red focal plane). (The latter should not be confused with lateral chromatic aberration in which a lens system corrected for axial chromatic aberration focuses different colors at different locations in the focal plane). FIG. 5b shows the primary lens focal distance changes for chromatic aberration and temperature shift.

In the figure, Blue color wavelengths are the dashed lines, solid colored lines are the Red color wavelengths. The temperature dependence of the polymer's index of refraction may be 0.0001 per degree Celsius or more, and causes the shift in focal length over temperature to be on the same order as the longitudinal axial chromatic aberration. Thus, a polymer Fresnel lens designed to focus all rays of a given wavelength to a given focal plane at a given temperature will exhibit different focal lengths for different wavelength, the whole focal region being shifted at different temperatures. This problem increases at high geometric concentration (1000× and above), where the focusing is tighter. Such a lens cannot effectively couple optical power to a small multi-junction photocell at any temperature, let alone over a large temperature range.

The temperature shift of silicone based Fresnel lenses directly impacts any secondary element designed to mitigate chromatic aberration. For example, the light entering a secondary kaleidoscopic prism will converge either at the top of the prism, or deep inside near the cell, depending on the temperature. This affects the number of bounces the different wavelengths make on the prism sidewalls, and thus the effectiveness of homogenizing the light distribution. This coupling of temperature and chromatic aberration effects has not been addressed in the prior literature.

The pattern of teeth may be organized into spiral/concentric rings of teeth or another repeating pattern where the teeth within a given ring of that pattern alternate in surface angle. The dimensions of the window of overlapping spot sizes is approximately equal to the anticipated axial shift in focal length, by approximately the same amount, with lens temperature change and/or chromatic aberration.

FIGS. 5a and 5b also show the surface angles of different teeth are interleaved in each of the two or more concentric rings in the ringed pattern across the lens and are set to create at least multiple focal points for two or more colors in the visible light spectrum to define the boundaries of the window of averaged intensity of light to reduce effects of lens temperature change on the light intensity distribution of different wavelengths in the focal zone/window of averaged intensity of light defined by the multiple focal points, in order to maintain good color mixing/spot size overlap for the two or more colors, best multi-layer solar cell efficiency, and averages out light intensity distribution across the surface of the multi-layer PV solar cell.

The target focus point for the focal length coming from that tooth is alternated within the set of different teeth to provide for multiple focal spots from different colors that overlap on the surface of the PV cell. For example, a first tooth in the pattern of teeth on the Fresnel lens has a different surface angle than a next neighboring tooth in the pattern of teeth on the Fresnel lens.

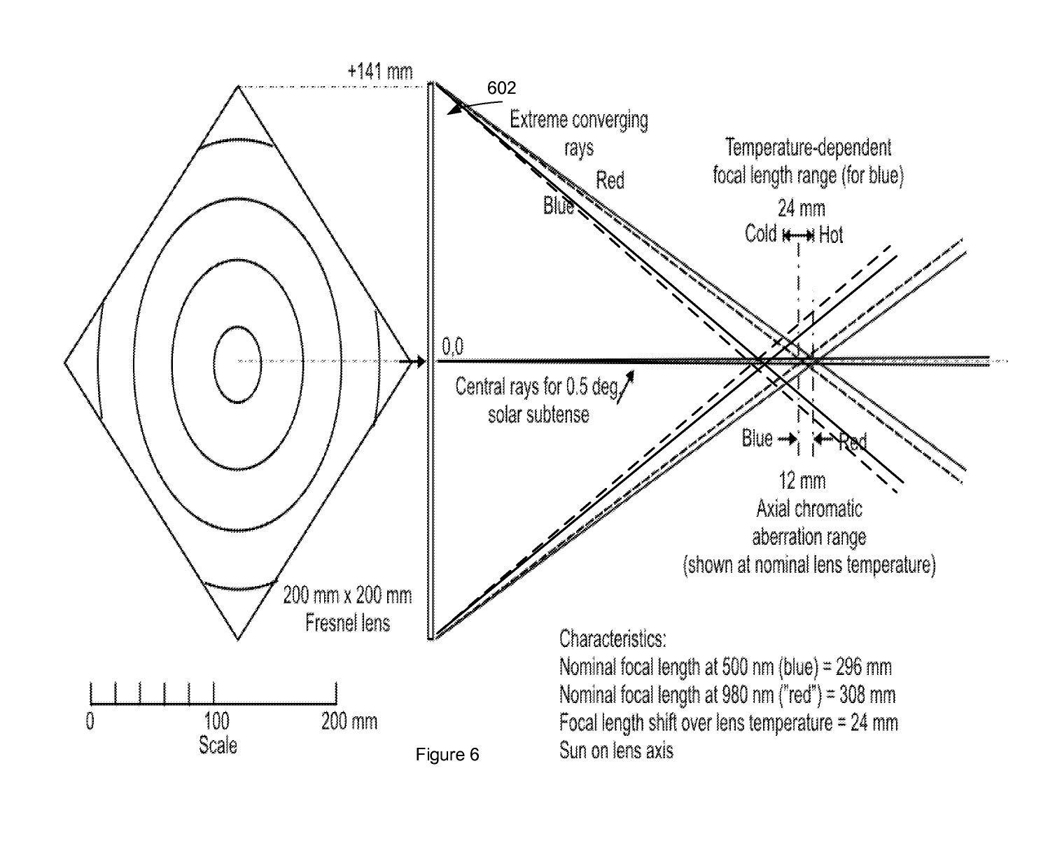

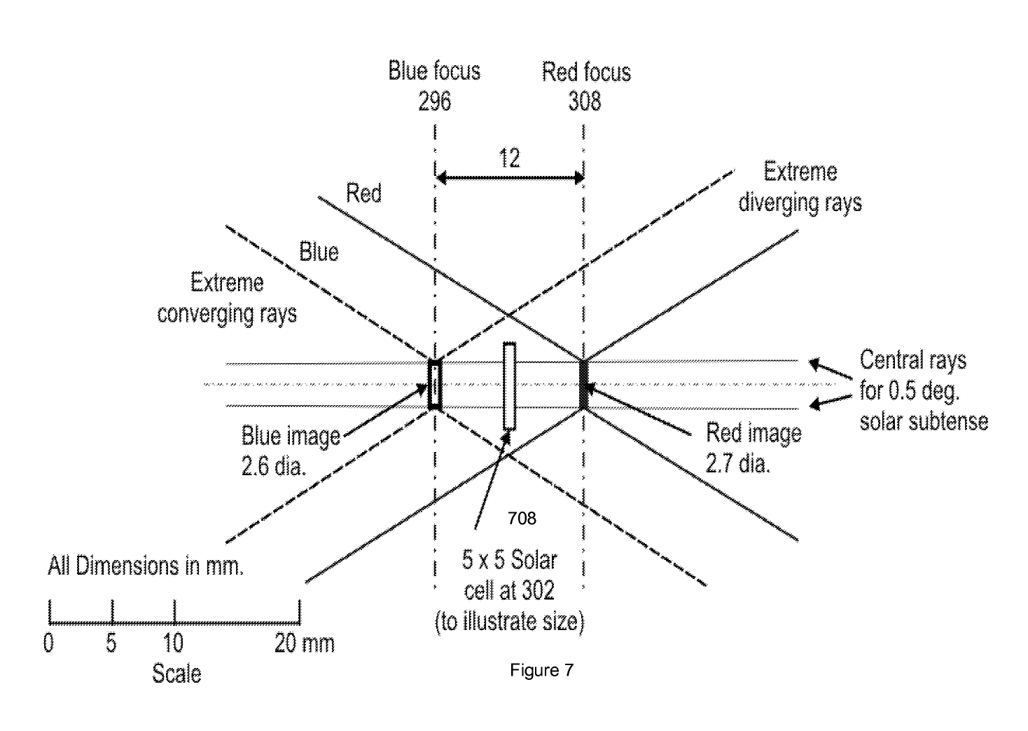

FIG. 6 illustrates a diagram of an embodiment of a set of teeth within a given ring of a ringed pattern of teeth 602 on the Fresnel lens having varying surface angles of different teeth across the lens. One set of teeth within the outer ring has a first target focal point. A second set of teeth within the outer ring has a second target focal point. For each target focal point, the difference in color wavelength and local of target focal point for that wavelength color is also shown. Note, the wide gap between target focal points has been exaggerated to make it more visually clear that two different target focal points are being aimed at. Also, FIG. 6 shows the extreme/edge ray envelopes for a point-focus 200×200 mm polymer Fresnel lens designed for a Blue (500 nm) focal length of 296 mm at nominal lens temperature. In the figure, Blue color wavelengths are the dashed lines, solid colored lines are the Red color wavelengths. FIG. 7 shows a diagram of an embodiment of the focal region of this lens using thin-lens central rays to approximate image sizes. The longitudinal axial chromatic aberration of this lens is 12 mm, such that the Red (980 nm) focal length at this temperature is 308 mm. The 5 by 5 mm PV cell 708 is in the middle of the window of averaged light intensity. A ray trace of this focal region shows that at the mid-point of the two foci, the two colors focal spots are roughly the same size, and this provides good overlap on the multi-junction cell. The ray traces for 500 nm (Blue) and 980 nm (Red) may overlap; and thus, span the overlap of the visible and possibly infrared spectrum overlap on the surface of the PV cell.

Referring to FIG. 8, the ray trace of a distributed focus design with 10 target points along 20 mm of the optical axis shows the intensity along the axis is more uniform than the two point design. Again, longer wavelengths would exhibit this same distribution of rays, simply shifted by the 12 mm chromatic aberration of the lens. The wider uniform region of intensity with the swept focus design provides better overlap of the spectral components on the solar cell, and provided more tolerance to focus shift due to temperature or assembly error, which effectively shift the cell position within this intensity distribution.

FIG. 8 quantifies the effect of lens design on the distribution of power in the focal zone at a given lens temperature for a ten target focal point design spaced at 3 mm intervals along a 30 mm axial range. Each graph plots the beam diameters (spot sizes) W for difference wavelengths vs. axial distance (offset) from the approximate location of the smallest spot. W is the Gaussian fit mode field diameter to the 1/e² power points (13.5% power points). That is, the rays within W represent 86.5% of the optical power transmitted by the lens at that wavelength. The increased averaging along the optical axis widens the region where the spot size is constant over wavelength at the expense of a slightly wider spot.

FIG. 9 illustrates example focal spot sizes for the different colors in the incident light of a lens designs with a single focal point. The focal zones of the lens designs for the single focal point in FIG. 9 and ten focal point design in FIG. 8 will shift axially by the same amount with lens temperature change, moving left (towards the lens) with temperature decrease and right with temperature increase. As the graphs and accompanying characteristics clearly indicate, the distributed focus lens design with three or more target focal points provides the smallest spot size change along the axis and hence the least change in spot size over lens temperature. This retains good color mixing on a multi-layer cell and improves cell efficiency over changes in lens temperature. For the distributed focus lens, a longer distribution of target spots would further increase the tolerance to axial shifting.

The design with multiple target focal points, for example eleven, reduces the effect of lens temperature change on the power distribution of different wavelengths in the focal zone; and thereby, maintains good color mixing for best multi-layer solar cell efficiency. Using only two focal spots provides only limited averaging. The design with three or more focal points allows for adjustment of the averaging in a controlled manner by adjusting the axial distance over which the foci (focal lengths) are spread, and the number of foci. Using only 5 to 15 focal spots, preferably 11 provides good averaging/allows for adjustment of the averaging in a controlled manner by adjusting the axial distance over which the foci (focal lengths) are spread, and the number of foci.

FIG. 8 shows the spots sizes of different wavelengths as a function of distance along axis around the focus for a distributed three or more focus target points Fresnel lens. The plot of the spot size for different wavelengths spans 400 nm to 1000 nm, for three lens designs. The zero position in the plots marks the point of smallest total spots size over all wavelengths. In the single point focus design, the effect of axial chromatic aberration is clearly seen in the variation of the spots sizes for each wavelength along the optical axis. The distributed three or more target focal point design shows the increase averaging along the optical axis widens the region where the spot size is constant over wavelength at the expense of a slightly wider spot. This design used a 30 mm long distribution with 10 target points spaced at 3 mm intervals. A longer distribution of target spots would increase the tolerance to axial shifting.

The ratio of the spot size/intensity distribution between Red and Blue color wavelengths should be less than 2:1 over the window of averaged intensity of light. As discussed, spot sizes of different wavelengths of the colors as a function of distance along axial axis vary. This distributed focus lens having five or more focal lengths interleaved across the set of teeth on the lens aimed at five or more different axial target focus locations increases averaging along the optical axis, and widens the window region where the spot size ratio between colors is relatively constant over the anticipated range of wavelengths during operation, at the expense of a slightly wider spot over that anticipated range of wavelengths. This design can use, for example, a 20 mm long distribution with 11 target focal points spaces at 3 mm intervals.

This alternation of the fringe focusing can have a radial as well as axial component. This is equivalent to focusing to different radius rings around the optical axis, at different target focal point locations along the optical axis. This degree of freedom controls the minimum averaged radial spot size, and thus the maximum intensity incident on the cell, while maintaining the axial averaging of light intensity.

Referring to FIGS. 3a and 3b, alternation of tooth focusing can have a radial and well as axial component. This is equivalent to focusing to different radius rings around the optical axis, at different positions along the optical axis. This degree of freedom controls the minimum radial spot size, and thus the maximum intensity incident on the cell, while maintaining the axial averaging.

A geometric analysis of extreme ray angles in the focal region suggests that it might be possible to further reduce the effect of lens temperature change by organizing the refractive zones on the lens such that the zones directing light to the extremes of the axial distribution range are located near the lens center.

Using only two focal spots provides only limited averaging. The three or more focal spots proposed here allows for adjustment of the averaging in a controlled manner by adjusting the axial distance over which the foci are spread, and the number of foci.

The distributed focal length and target focal point Fresnel lens is used to construct the solar array with its flat, square Fresnel lens of relatively short focal length (low F/#). The distributed focal length Fresnel lens with concentric rings to mitigate chromatic aberration and changes in focal length due with changes in temperature. The Fresnel lens may reduce or eliminate chromatic aberration.

Designing the Fresnel lens to mitigate chromatic aberration is a benefit since it adds relatively no additional cost or loss elements to the system. 20 mm and 30 mm axial line swept Fresnel lenses could be made. This design also improves manufacturability of the solar concentrator arrays.

### The Total Internal Reflection (TIR) Prism Secondary

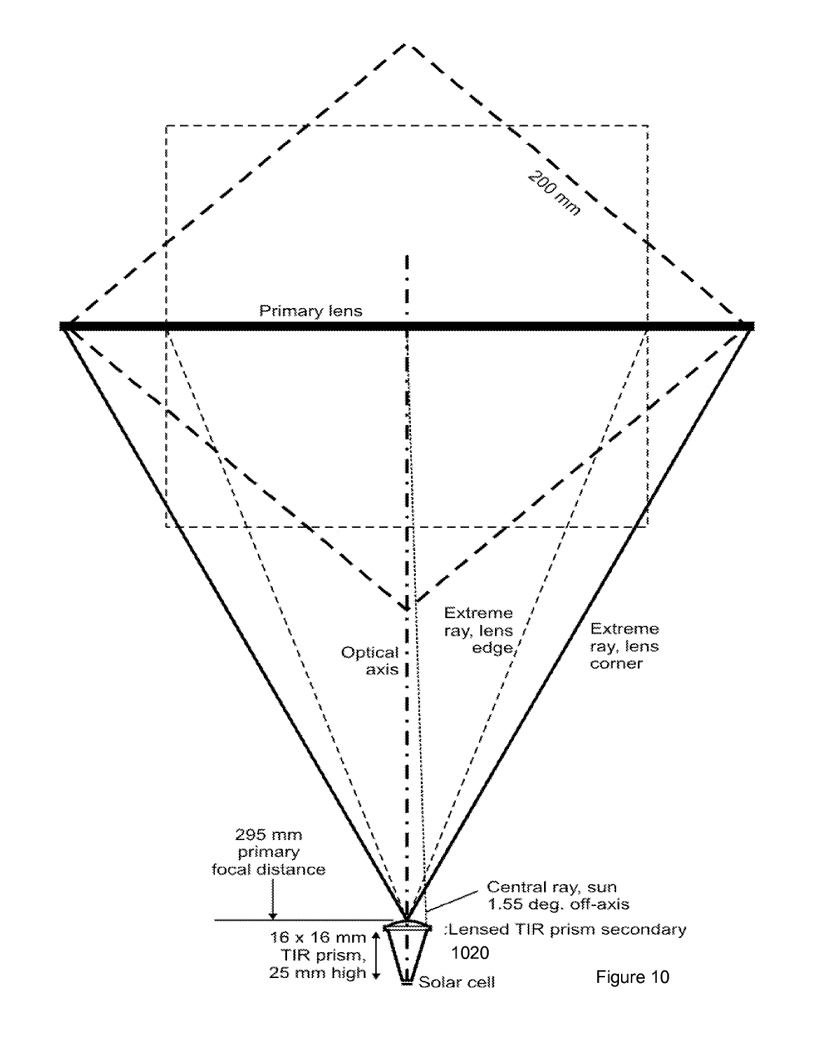

FIG. 10 illustrates a diagram of an embodiment of a total internal reflection prism having a domed shaped top portion and trapezoidal bottom portion that is used as a secondary concentrating mirror surface for the multiple junction photovoltaic cell. The trapezoidal bottom portion of the prism has walls. The total internal reflection prism 1020 is optically coupled between the multiple junction photovoltaic cell and any primary lens, for example the Fresnel lens with teeth. The secondary concentrating mirror surface increases concentration in number of suns intensity impinging the cell active area of the multiple junction photovoltaic cell over the primary lens by itself. When the primary lens is the Fresnel lens with teeth, the lens redirects light rays via the set of teeth to the domed shaped secondary concentrating mirror, which then reflects the concentrated beam of light to within the walls of the trapezoidal shaped portion of the prism and onto the multiple junction photovoltaic cell. The domed shaped top portion and trapezoidal bottom portion are created as a single-piece/monolithic secondary optic that provides a larger acceptance angle than the trapezoidal bottom portion by itself, while also providing good homogenization of the light intensity across the surface of the multiple junction PV cell.

In this single element Fresnel lens, light couples onto a secondary optic of an internal reflection prism placed above the active surface of the solar cell in this two-stage concentrated photovoltaic (CPV) system. The secondary optic is designed to perform or several of the following functions:

A) Increase concentration. The efficiency of multi-junction cells increases with the optical power concentration ratio, reaching a maximum typically the 500 to 1000 “suns” range. The concentration in number of suns is defined as the ratio of the average intensity impinging the cell active area divided by 0.1 W/cm2.

B) Increase acceptance angle. The optical train must provide a sufficiently large acceptance angle of direct plus circumsolar (D+C) light to accommodate achievable tracker pointing accuracy. Acceptance angle is defined as the pointing error at which the light impinging the cell drops to 90% of the on-axis (maximum) level. Total internal reflection may be thought of as an optical phenomenon that happens when a ray of light strikes a medium boundary at an angle larger than a particular critical angle with respect to the normal to the surface. If the refractive index is lower on the other side of the boundary, no light can pass through and all of the light is reflected. The critical angle is the angle of incidence above which the total internal reflection occurs.

C) Homogenization. Although there is no need to form an image of the solar disc on the cell, the peak efficiency of a multi-junction solar cell can only be achieved if the convertible spectra are spatially overlaid. This action is called homogenization or color mixing.

The single-piece secondary optic provides a larger acceptance angle than designs presently in use, while also providing good homogenization. The domed secondary with a trapezoidal bottom enables these requirements to be satisfied. Indeed, the use of a convex power surface provides matching between the angular spectrum of the light converging from the primary and the acceptance angle limits of the homogenizing prism, which vary over its surface.

The shape of the surface of the refractive dome is such that incident light rays that are outside the acceptance angle of the trapezoidal prism by itself are bent by the surface of the dome to enter the plane starting the trapezoidal portion to be within the acceptance angle of the trapezoidal portion and propagate to the solar PV cell to provide good homogenization, while the shape of the surface of the refractive dome kaleidoscopic prism effect for intensity homogenization and color mixing. The secondary optics with the proposed dome top and trapezoidal bottom shape employ reflection and may be implemented as solid glass or plastic bodies. The solid forms cause some refraction at the entrance face, but this is largely incidental to light propagation to the exit face. The solid forms utilize the principle of total internal reflection (TIR) at the side walls.

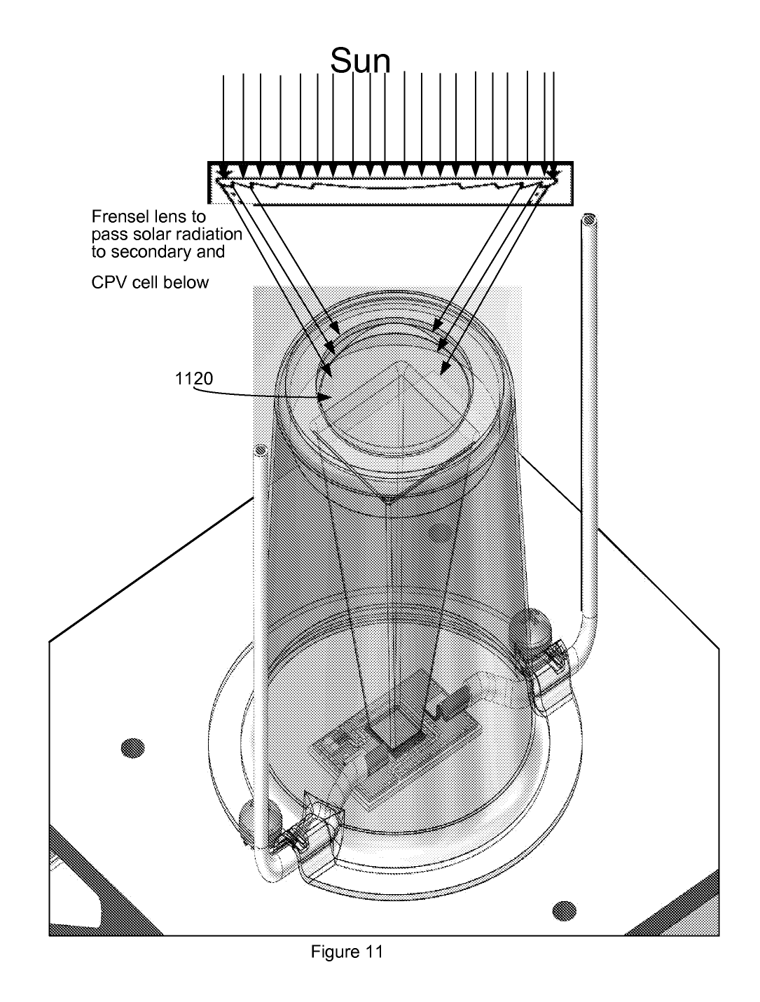

FIG. 11 illustrates a diagram of an embodiment of a Fresnel lens directing light to a secondary optic to concentrate solar radiation to a photovoltaic cell in a receiver assembly. The receiver with the Fresnel lens optically coupling to the photovoltaic cell may make a CPV power unit. The Fresnel lens passes and directs the angle of the solar radiation to a receiver containing a secondary optic and the photovoltaic solar cell. The Fresnel lens directs light to the dome of the secondary optic 1120. The solar cell under the secondary prism is a multi-layer/multi-junction device designed to convert as much of the solar spectrum reaching the surface of the solar cell as feasible. The Fresnel approach also gives the design more degrees of freedom to improve performance, and compensate for other non-ideal elements in the system. The Fresnel approach may enable the use of a spherical secondary, since the primary can compensate for spherical aberration and coma. This may reduce cost in forming the secondary mirror or mold. The secondary enables a monolithic, or solid core panel design, with no air gaps or spaces. This improves reliability be reducing the number of optical surfaces and eliminating water condensation. The secondary optic may be a total internal reflection prism optically coupled to the Fresnel lens.

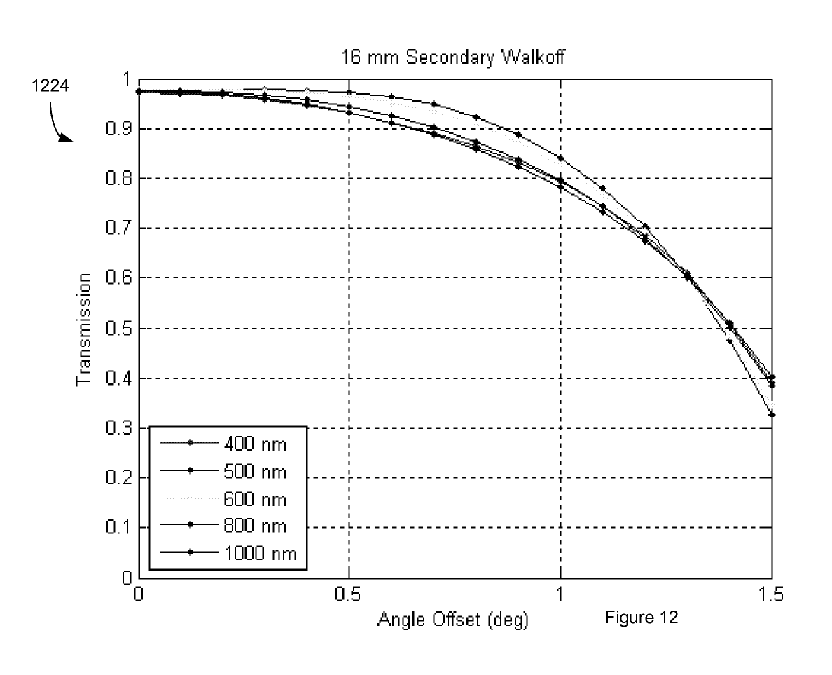

FIG. 12 Illustrates an example graph 1224 of an embodiment of an example calculated secondary walkoff transmission through a 16 mm aperture versus incidence angle. The transmission through a 16 mm diameter aperture located in the focal plane of the primary lens, and when used with a multiple target focal point Fresnel lens in the middle of the window defined by the target focal points. This analysis included the effect of chromatic aberration as well as off-axis aberrations such as coma that increase the size of the focused spot as it moves off axis.

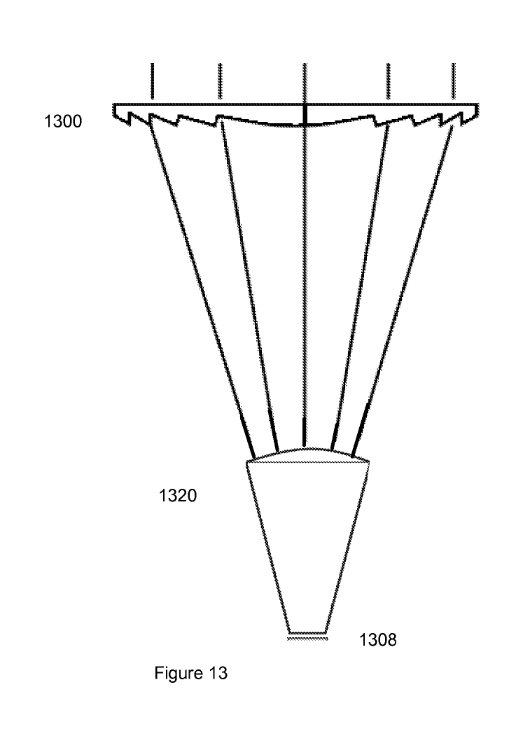

FIG. 13 illustrates a diagram of an embodiment of a Fresnel lens 1300 focusing light to the secondary 1320 shaped to concentrate that light onto the underlying PV cell 1308. The dome shaped top portion has dimensions that couples the incident light beam to a maximum transmission characteristic of the trapezoidal prism body, which both improves homogenization of light intensity across the surface of the PV cell optically coupled to this secondary optic and minimizes leakage of incident light from the primary optic reaching the surface of the PV cell. This both improves homogenization and minimizes leakage.

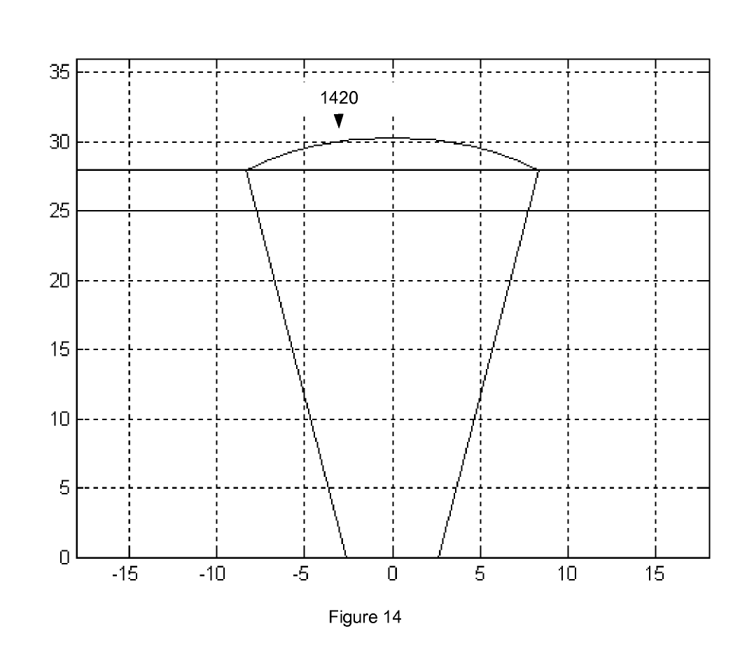

FIG. 14 illustrates a diagram of an embodiment of the secondary optic 1420 working by fitting a trapezoidal TIR prism with a curved front surface (dome) that refracts the incident light beams from the primary Fresnel lens into alignment with the trapezoidal portion of the prism's acceptance angle as the incident light beams from the primary Fresnel lens walk across a face of the curved front surface of the secondary optic. Relative to a conventional flat-top trapezoidal TIR prism of the same aperture, the domed prism provides higher multi-junction solar cell photocurrent over a wider system acceptance angle and is more tolerant of primary lens focal distance variation due to chromatic aberration and temperature.

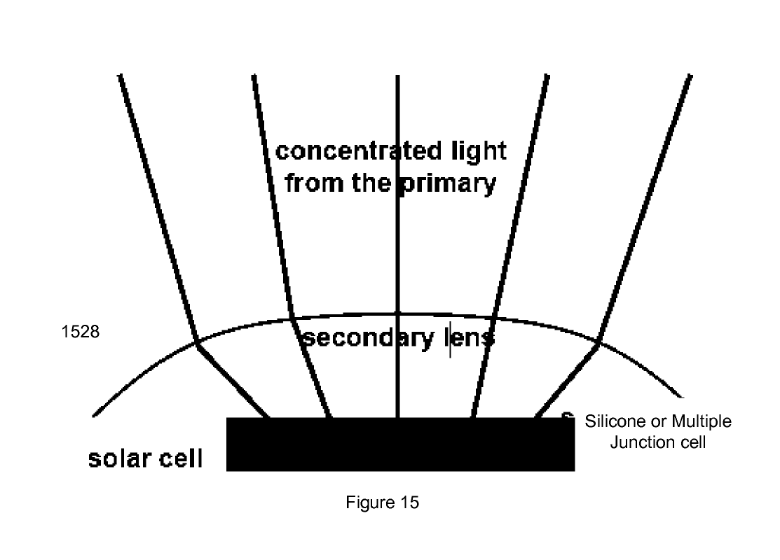

FIG. 15 illustrates a diagram of an embodiment of the shape of the refractive secondary dome 1528, i.e. a plano-convex thick lens, and illustrates the concentrating action of such a device.

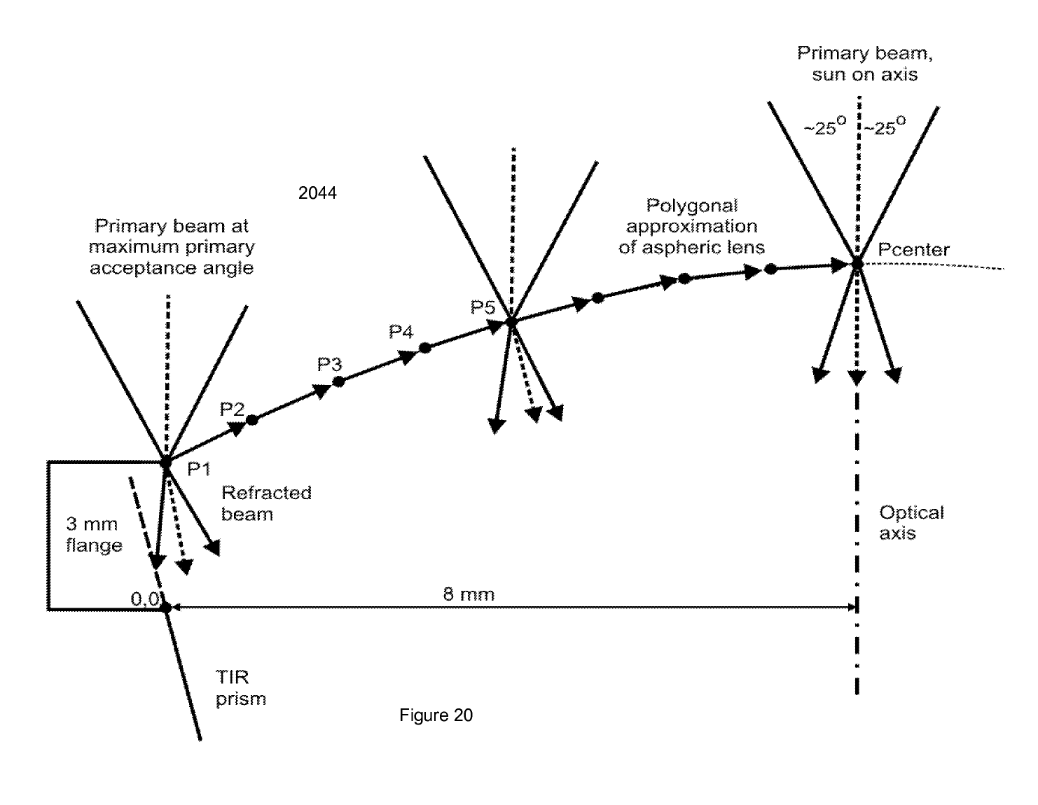

FIG. 20 illustrates a diagram of an embodiment of an aspheric lens profile construction 2044. The tilt of the acceptance angle limits in the top plots of FIG. 20 suggests that a convex surface could be used to refract the primary beam into the acceptance limits of the prism. The simple polygonal approximation procedure illustrated in FIG. 10 was used to calculate the required surface, in this case for a 16×16×25 mm prism. Point P1 is located 3 mm above the edge of the prism's aperture to allow for a 3-mm thick molding flange (the near side wall of the prism is extended into the flange volume for the analysis).

Using the all-incident-angle ray trace, the slope of a solid-air planar interface at P1 is determined that centers the refracted primary beam in the TIR prism's angular acceptance range. Point P2 is located in the P1-defined plane at an incremental distance towards the system optical axis. The primary beam incidence point is moved to P2 and the method repeated to find the desired slope at P2. This process is repeated until the optical axis is reached, at which point the surface will be normal to the prism axis by symmetry. This procedure results in a polygon approximation to the optimal curve.

An analytical expression can be found by taking sufficiently small step sizes and fitting the resulting points to a conic formula.

Because the optimization was conducted in 2D, the transmission performance of these domed secondary prisms was verified by 3D ray tracing. The apex of each secondary entrance face was located in the 295 mm focal plane of the primary. A plot of the resulting secondary transmission vs. system pointing error and confirms the expected performance. Transmission is defined as the ratio of the power incident at the top of the secondary to the power exiting the bottom surface of the secondary.

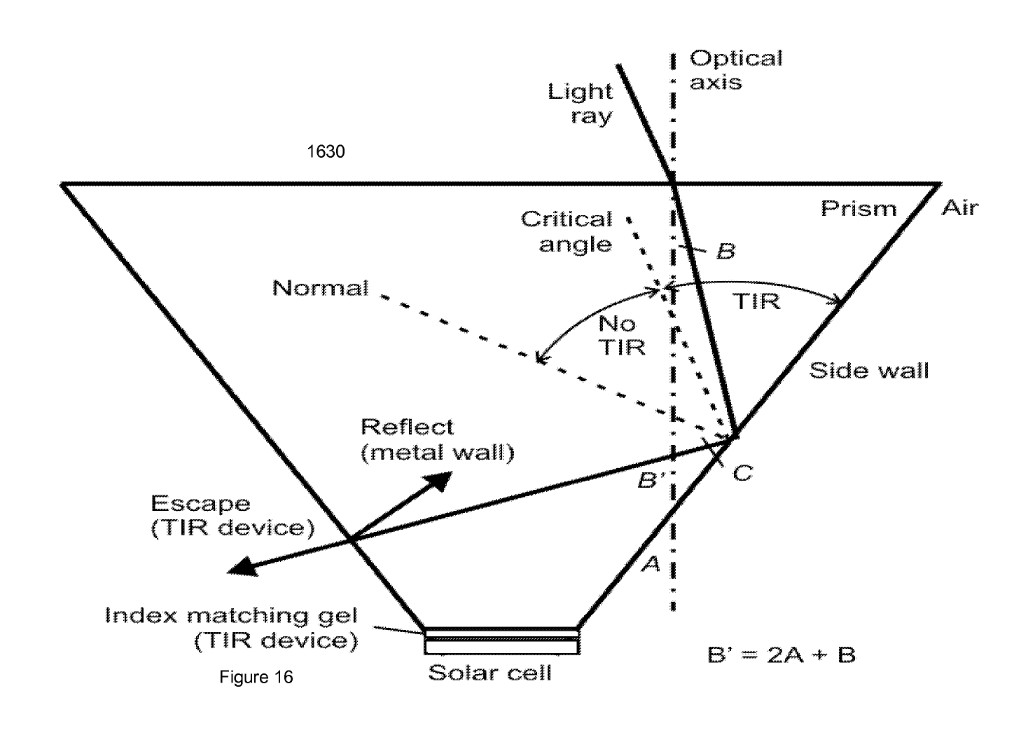

FIG. 16 illustrates a diagram of an embodiment of example TIR action in a trapezoidal portion 1630 of the prism. The TIR for a trapezoidal prism shows sideways are tilted at angle A with respect the optical axis. A light ray enters the prism and propagates at angle B with respect to the optical axis after refraction at the entrance face. If the ray strikes the side wall at an angle C with respect to the surface normal that is greater than the critical angle for the prism-air interface, it is total reflected.

The critical angle is the angle whose sine is the ratio of the outboard to inboard index of refraction. For example, for an acrylic body (index 1.50) in air (index 1.00), the critical angle is arcsin (1.00/1.50)=41.8 degrees from the normal. For steeper angles (angles less than the critical angle), the light is partially reflected and partially transmitted through the interface according to Snell's law. After the first side wall reflection, the ray angle with respect to the optical axis has increased to B′=2A+B. For the case shown, the ray strikes the opposite wall at too steep an angle for TIR and escapes. Dielectric (“anti-reflective”) coating of the prism side walls has little effect on the TIR characteristics. Ray angles larger than a certain limit will be reflected back after a number of bounces (on second bounce as shown here) and not propagate to the solar cell.

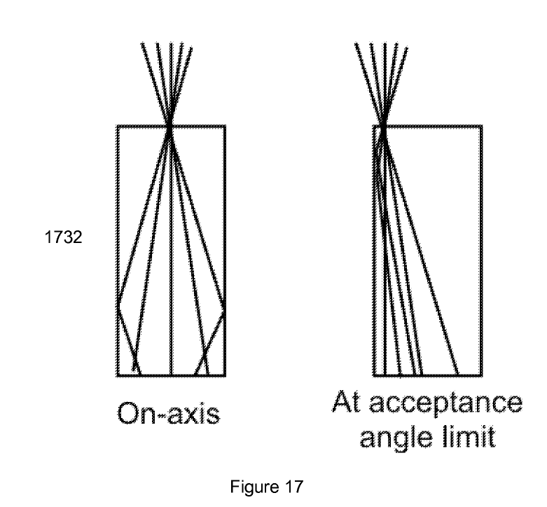

This domed shaped top and tapered bottom prism does increase acceptance angle, and spreads the light over the surface of the PV cell face as the primary lens focal spot walks across the prism aperture. The trapezoidal prism provides homogenization. A ray trace of 450-1700 nm light in a trapezoidal with a square cross-section provides “kaleidoscopic” homogenization. In the top picture, the aberrated beam from the primary lens enters the prism with 3.8 mm of lateral margin and is reflected onto the exit face having about the same areas as the entering beam waist. In the bottom picture, tracking error has moved the beam to near the edge of the prism aperture. FIG. 17 illustrates an example of TIR action in a rectangular shaped prism homogenizer 1732 rather than a trapezoidal shaped prism. Unlike the rectangular prism, the trapezoidal prism increases acceptance angle.

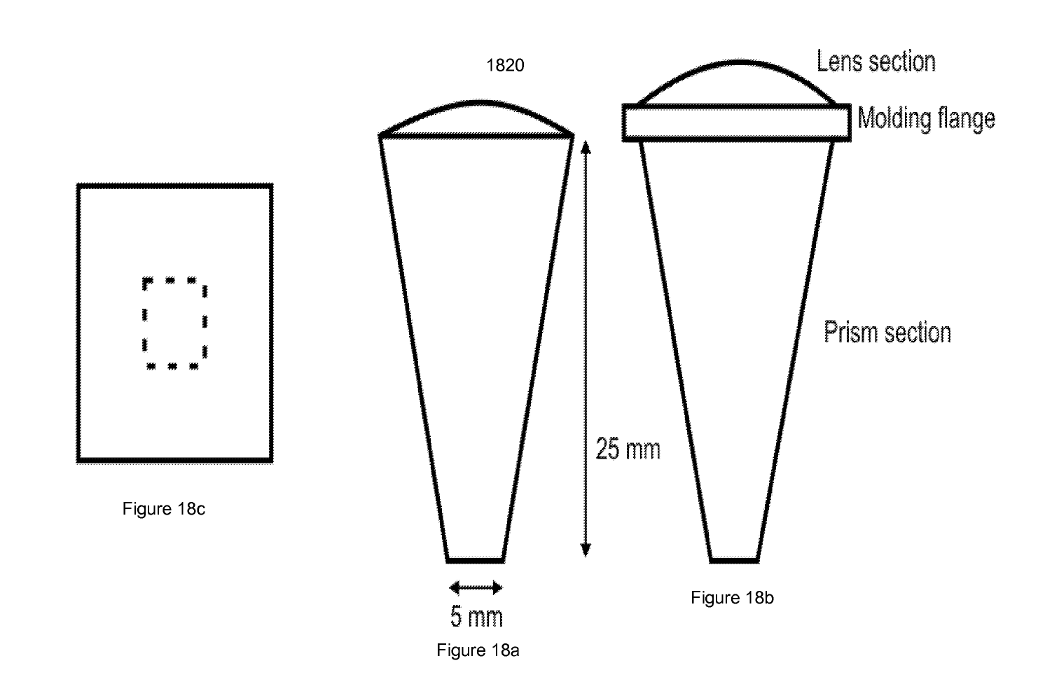

FIGS. 18a-c illustrate diagrams of an embodiment of a single-element domed shape top that increases transmission of light through to a flat-top prism 1820. FIG. 18a shows the molded secondary optic combines a convex lens front surface, or dome, with a TIR trapezoidal prism body. This arrangement preserves the homogenizing properties of the prism while increasing angular acceptance. The dimensions shown are appropriate for use with an example 5×5 mm solar cell, although the element can be scaled for any cell size. The domed surface is located on top of the tapered lower portion of the prism. FIG. 18b shows a flange portion of the prism facilitates molding and also facilitates subsequent mounting in the solar power unit. FIG. 18c shows a top down view of the crown of the dome in the middle and widening out to the trapezoidal sides of the prism.

The domed shaped top portion convex dome surface is used to refract the primary beam into the acceptance limits of the trapezoidal portion of the monolithic prism by matching of the incoming angular distribution to the TIR prism acceptance.

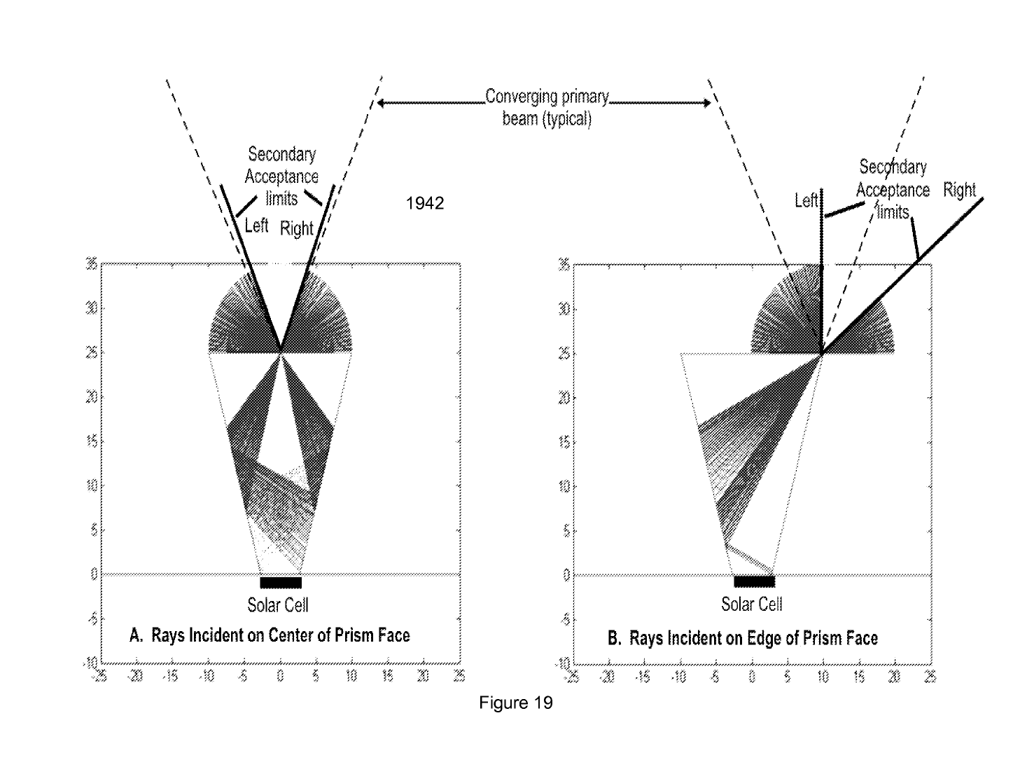

FIG. 19 shows an example graph 1942 of ray tracing results for a standard flat-top trapezoidal TIR prism of acceptance vs. incidence angle of light from the primary lens. The ray trace shows the angular acceptance of a flat-top trapezoidal TIR prism.

The left figure shows the propagation paths over all incidence angles for the light rays that are incident on a spot at the center of the prism entrance face. Ray paths colored yellow (very light gray in non-color print) propagate to the bottom of the prism and couple to the solar cell. Ray paths colored Red (dark gray in non-color print) violate TIR at some point and much of their power is lost (rays leaking from the prism are truncated at the prism sidewall for clarity).

The right figure gives the same analysis an incidence point at the extreme edge of the prism entrance face. As this point moves from the center to the edge of the prism face, the acceptance range tilts as shown. The reason for this effect can be understood by reviewing the ray path principles shown in FIG. 19. As the incident point moves off-axis, some rays propagating into the prism strike higher on the sidewalls and thus undergo multiple side-wall encounters. Some portion of these rays will violate TIR at some encounter, part of the power escaping through the side wall and part of the power reflected, possible to escape at the entrance face. Thus, the incident rays must be aligned more parallel to the nearest sidewall to minimize the number of bounces to reach the bottom. The resulting tilt of the acceptance range partially decouples the prism from the primary lens beam, resulting in loss of system optical efficiency.

FIG. 19 shows the results of a ray tracing method for a 25 mm tall trapezoidal prism having a 16×16 mm entrance face.

The top plot shows the left and right acceptance angle limits with respect to the prism axis. The angular magnitudes are divided by two to facilitate the convention of expressing acceptance as a half-angle (pointing error). The slope changes are due to changes in the number of bounces required to reach the bottom as the incident point is moved. The bottom plot set shows the prism acceptance half angles (difference between the positive and negative limit angles/2) vs. incidence point offset, compared with the half angle of the focused light beam from the 200×200 mm Fresnel primary. The latter, as calculated for the full corner-to-corner aperture of the primary is on the order of 33 degrees. However, most of the primary beam power is contained in the narrower half-angle of some 25 degrees computed as though the primary were a 200 mm diameter disk (“edge-to-edge”).

The angular bandwidth seen in the lower plot shows that the prism acceptance is matched to the incident light beam up to the point where the incident beam walks off the prism face. The problem is that this angular bandwidth is offset from the incident light angular spectrum as evidences by the tilt of the Blue curves in the top plot.

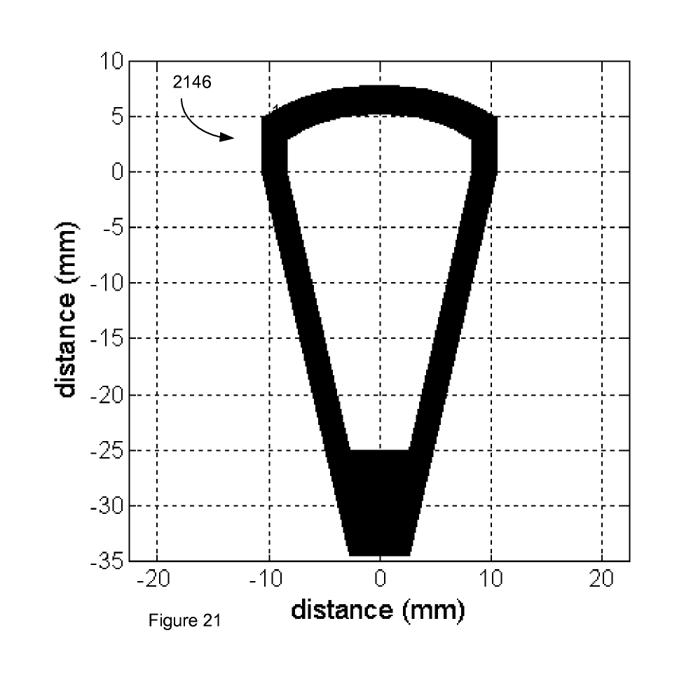

FIG. 21 illustrates a diagram of an embodiment of range of dimensions of the curvature of the domed surface, which is set to match the angular distribution of the light from the primary focus element to the acceptance angles of the TIR trapezoidal portion of the prism. The figure shows an example front surface solution for a 16×16×25 mm TIR prism body.

The shaded area 2146 of FIG. 21 is an example envelope of efficient angular spectrum matched designs for a 5.5 mm solar cell and an F1.0 primary at geometric concentration of approximately 1300×.

The curvature of the domed surface is set to match the angular distribution of the light from the primary focus element to the acceptance angles of the TIR trapezoidal portion of the prism. The distance of the radius of the dome from the center of the surface of the flat portion of the trapezoidal prism is inversely proportional to either 1) the width dimension of the flat portion of the trapezoidal prism, 2) the diagonal dimension of the flat portion of the trapezoidal prism, or 3) a distance set anywhere between the width dimension of the flat portion of the trapezoidal prism and the diagonal dimension of the flat portion of the trapezoidal prism. This shaded area 2146 in FIG. 21 forms an envelope of dimensions of the shape of dome relative to flat top of trapezoidal prism for efficient angular spectrum matched designs.

The inner boundary of the shaded area 2146 in FIG. 21 has an outer boundary consists of a 34.5 mm tall prism, with square dimensions of 5.5 mm at the bottom and 20 mm at the top. This prism volume is capped by a 5.0 mm molding flange and a lens of radius of curvature 22.9 mm with a conic of 1.55. Cost and technological considerations of the molding process will drive the design to the smallest possible size, whereas walk-off of the primary focal spot of the secondary aperture will set a limit to the minimum possible dimension.

For a 1 degree system pointing error (tilt), the transmission of the flat top prism rolls of to less than 70% for all wavelengths. By adding the dome, the transmission of the visible wavelengths (450 nm to 650 nm) remains above 85% at this pointing error.

Effect of Domed Prism on Triple Junction Solar Cell Photocurrent in Two-Stage System.
Primary lens chromatic aberration. A silicon-on-glass primary lens of 295 mm focal length may exhibit longitudinal axial chromatic aberration of 10 mm or more (FIG. 5b-left).
Primary lens focal length vs. temperature. The same lens may exhibit a focal length vs. temperature shift of 20 mm or more (FIG. 5b—right).
Multi-junction solar current vs. homogenization. For a given incident spectrum, a multi-junction solar cell produces maximum photocurrent when the spectra to which the various junctions are sensitive are spatially overlaid as in FIGS. 4A-4D.

Real system performance must be determined by calculating the triple junction cell photocurrent. The goal is to achieve a 90% maximum roll-off in photocurrent at 1 deg tilt angle. The domed prism produces more photocurrent at all focal distances and tilt angles, and achieves the 1 degree acceptance angle goal at focal distances between 285 and 300 mm.

Z-axis range: 270 to 320 mm in 10 mm steps, primary focal plane at 295 mm.

The dome coupled to the flat top of the trapezoidal prism reduces system performance degradation caused by aberration- and temperature-related primary lens focal distance changes.

Thus, the secondary prism design incorporates a domed surface on top of a tapered prism. This design realizes the benefits of a kaleidoscopic prism for intensity homogenization and color mixing, while increasing the system acceptance angle. Additionally, this design method for the lens surface enables matching of the angular distribution of the light from the primary focus element to the acceptance angles of the TIR prism section.

An example realization of the design is a 16×16×25 mm prism capped with an aspheric lens prescribed by a radius of curvature of 18.2 mm with a conic constant of +1.908. Such a lens is designed for a primary operating at F1.0, with a chip size of 5.5 mm on a side. Scaling to different chip sizes is straight-forward, resulting is a direct scaling of all the linear dimensions. Using different F# for the primary with change the taper angle of the homogenizing prism section. Smaller F# will result in a steeper angle for the prism. The focal length of the primary will control the aperture size of the homogenizing trapezoidal portion of the prism, and therefore of the aperture size of the domed shaped lens cap as well. This aperture size will scale directly with the focal length due to walk-off considerations as plotted in FIG. 12 where a 290 mm primary focal length was used. Regardless of these starting parameters of the primary design, and the system geometric concentration target, this secondary design will provided an efficient coupling to the solar cell, with the widest possible acceptance angle.

The key concept of this design is the matching of the incoming angular distribution to the TIR prism acceptance, which fills this prism angular bandwidth, in that way ensures homogenization at the chip. The analytical method results in a starting point for optimization, and does not provide the only design with sufficient acceptance angle matching. 3D ray-tracing can be performed using the 2D method design as a starting point, to further optimize the prism dimensions and lens shape. FIG. 21 plots and enveloped of essentially equivalent design, in that they provide wide acceptance angle with good homogenization over a 5.5 mm chip. As stated, above, scaling to other chip sizes is within the skill of a person in the art.

The section above analyzes three or more embodiments, and discusses design ranges and scaling. This secondary element can be either formed from a single piece of dielectric, or bonded or mounted as separate pieces to achieve the same optical function. The methods disclosed herein can be readily applied to solar collection systems having different focal length primary lens, different size photocells, and/or photocells having different spectral response characteristics. For the primary Fresnel lens with sets of teeth, the design can also interleave teeth with materials made of different refractive indexes to achieve the multiple different focal lengths distributed over multiple target focal points.

The physical and electrical arrangement of modules in a representative tracker unit. There may be 24 power units per module, eight modules per paddle, two paddles per tilt axis, and four independently-controlled tilt axes per common roll axis. A bi-polar voltage from the set of paddles may be, for example, a +600 VDC and a −600 VDC making a 1200 VDC output coming from the 16 PV modules. The 16 PV module array may be a string/row of PV cells arranged in an electrically series arrangement of two 300 VDC panels adding together to make the +600 VDC, along with two 300 VDC panels adding together to make the −600 VDC.

While some specific embodiments of the invention have been shown the invention is not to be limited to these embodiments. The invention is to be understood as not limited by the specific embodiments described herein, but only by scope of the appended claims.

We claim:

1. An apparatus for a photovoltaic (PV) system; comprising:
a PV power unit that has a Fresnel lens with a plurality of teeth, which provide a distributed set of two or more axial focal lengths to mitigate chromatic aberration as well as changes in focal length due to changes in temperature of the material forming the lens with teeth; and
a multiple junction photovoltaic cell optically coupled to the Fresnel lens with teeth, where a set of teeth within a given ring of a ringed pattern of teeth on the Fresnel lens have 1) varying surface angles of different teeth across the lens, 2) varying refractive indexes of the different teeth or 3) a combination of both, to establish multiple focal lengths aimed at five or more different axial target focal points within an anticipated zone of operation relative to the multiple junction photovoltaic cell in order to create a window of averaged intensity of light defined by the five or more different axial target focal points, and the width of the window of averaged intensity of light is at least as large as the size of the multiple junction photovoltaic cell.

2. The apparatus for the PV system of claim 1, where the surface angles of different teeth are interleaved in each of the two or more concentric rings in the ringed pattern across the lens and are set to create at least multiple focal points for two or more colors in the visible light spectrum to define the boundaries of the window of averaged intensity of light to reduce effects of lens temperature change on the light intensity distribution of different wavelengths in the window of averaged intensity of light defined by the multiple focal points, in order to maintain good color mixing/spot size overlap for the two or more colors, and averages out light intensity distribution across the surface of the multi-layer PV solar cell.

3. The apparatus for the PV system of claim 1, where the different target focal points for the set of teeth are spaced set distances apart such that the set of different target points spans a distance making a window of operation centric around the multiple layer solar PV cell under nominal conditions.

4. The apparatus for the PV system of claim 1, where the ratio of the spot size/intensity distribution between Red and Blue color wavelengths in the window of averaged intensity of light should be less than 2:1 over the window; and thus, the spot size ratio between colors is relatively constant over an anticipated range of wavelengths during operation at an expense of a slightly wider spot over that anticipated range of wavelengths.

5. The apparatus for the PV system of claim 1, where the mapping of the surface angle of the teeth of the lens to the target focal points is to divide the Fresnel lens into a number of concentric rings, with each ring focusing to one of the target focal length points, where the number of teeth in each ring can be adjusted to provide equal power to each target focus point, and the target focus points are selected so that the spot sizes of the different colors in the incident light will significantly overlap in the window established by the locations of those multiple target focus point.

6. The apparatus for the PV system of claim 1, where the mapping of the surface angle of the teeth of the lens to the multiple different target focal points by interleaving the teeth with alternating surface angles of the teeth within a given group or ring of teeth in the ring pattern to create the multiple different target focus points to create the averaging window of light intensity centric around the focal length of the multiple junction PV cell.

7. The apparatus for the PV system of claim 1, where the index of refraction of the material forming the lens with teeth, including a polymer substance, is characterized by both large wavelength dependence over a solar radiation spectrum of interest as well as large temperature dependence over an anticipated range of operation of the PV power unit.

8. The apparatus for the PV system of claim 1, where the set of different axial focal points lengths generated by the differing surface angles of the teeth are chosen to be spaced a set distance apart to create the window of averaged intensity of light with overlapping spot sizes/intensity distribution on the surface of the PV cell for different colors in the light wave spectrum which approximately matches 1) an amount of shift in focal length due to anticipated chromatic aberration during operation, 2) the amount of shift in focal length due to change in refractive index of the material making up the teeth due to temperature changes over the normal range of operation of the PV power unit, or 3) both.

9. The apparatus for the PV system of claim 1, further comprising:
a total internal reflection prism having a domed shaped top portion and trapezoidal bottom portion that is used as a secondary concentrating mirror surface for the multiple junction photovoltaic cell,
where the trapezoidal bottom portion of the prism has walls,
where the total internal reflection prism is optically coupled between the multiple junction photovoltaic cell and the Fresnel lens with teeth,
where the secondary concentrating mirror surface increases concentration in number of suns intensity impinging the cell active area of the multiple junction photovoltaic cell over the Fresnel lens by itself, and
where the Fresnel lens redirects light rays via the set of teeth to the domed shaped secondary concentrating mirror, which then reflects the concentrated beam of light to within the walls of the trapezoidal shaped portion of the prism and onto the multiple junction photovoltaic cell.

10. The apparatus for the PV system of claim 9, where the domed shaped top portion and trapezoidal bottom portion are created as a single-piece/monolithic secondary optic that provides a larger acceptance angle than the trapezoidal bottom portion by itself, while also providing good homogenization of the light intensity across the surface of the multiple junction PV cell.

11. The apparatus for the PV system of claim 9, where the domed shaped top portion convex surface is used to refract light beams from the Fresnel lens into the acceptance limits of the trapezoidal portion of the monolithic prism by matching of the incoming angular distribution to the TIR prism's acceptance angle, and
where a flange portion of the prism facilitates molding and also facilitates subsequent mounting of the prism in the PV power unit.

12. The apparatus for the PV system of claim 9, where a curvature of the domed surface is set to match the angular distribution of the light from the Fresnel lens to the acceptance angles of the TIR trapezoidal portion of the prism, and
where a distance of the radius of the dome from the center of the surface of the flat portion of the trapezoidal portion of the prism is inversely proportional to either 1) the width dimension of the flat surface portion of the trapezoidal prism, 2) the diagonal dimension of the flat surface portion of the trapezoidal prism, or 3) a distance set anywhere between the width dimension of the flat surface portion of the trapezoidal prism and the diagonal dimension of the flat surface portion of the trapezoidal prism.

13. The apparatus for the PV system of claim 1, further comprising:
a total internal reflection prism having a domed shaped top portion and trapezoidal bottom portion that is used as a secondary concentrating mirror surface for the multiple junction photovoltaic cell,
where the total internal reflection prism is optically coupled between the multiple junction photovoltaic cell and the Fresnel lens with teeth, and
where the dome shaped top portion has dimensions that couple the incident light beam to a maximum transmission characteristic of the trapezoidal portion of the prism body, which both improves homogenization of light intensity across the surface of the PV cell optically coupled to this TIR prism secondary optic and minimizes leakage of incident light from the Fresnel lens primary optic reaching the surface of the PV cell.

14. The apparatus for the PV system of claim 1, where the target focus point for the focal length coming from each tooth in the set of teeth in a given ring of the ringed pattern is alternated within the set of different teeth to provide for multiple focal spots from different colors that overlap on the surface of the PV cell; and thus, a first tooth in the pattern of teeth on the Fresnel lens has a different surface angle than a next neighboring tooth in the pattern of teeth on the Fresnel lens.

15. The apparatus for the PV system of claim 9, where the shape of the surface of the refractive dome is such that incident light rays that are outside the acceptance angle of the trapezoidal prism by itself are bent by the surface of the dome to enter the plane starting the trapezoidal portion to be within the acceptance angle of the trapezoidal portion and propagate to the solar PV cell to provide good homogenization, while the shape of the surface of the refractive dome kaleidoscopic prism effect for intensity homogenization and color mixing.

16. The apparatus for the PV system of claim 1, further comprising:
a secondary optic between the Fresnel lens and the PV cell, where the shape of the secondary optic is a trapezoidal TIR prism fitted with a curved front surface that refracts the incident light beams from the primary Fresnel lens into alignment with the trapezoidal portion of the prism's acceptance angle as the incident light beams from the primary Fresnel lens walk across a face of the curved front surface of the secondary optic.

17. A method for a concentrated photovoltaic system, comprising:
optically coupling a multiple junction photovoltaic cell to a Fresnel lens with teeth;
configuring a set of teeth within a given ring of a ringed pattern of teeth on the Fresnel lens to have 1) varying surface angles of different teeth across the lens, 2) varying refractive indexes of the different teeth or 3) a combination of both; and
where the differing surface angles or refractive indexes of different teeth within a given ring of a ringed pattern of teeth establish multiple focal lengths aimed at five or more different axial target focal points within an anticipated zone of operation relative to the multiple junction photovoltaic cell to create a window of averaged intensity of light defined by the five or more different axial target focal points.
